(19) United States
(12) Patent Application Publication
(10) Pub. No.: US 2014/0321077 A1
(43) Pub. Date: Oct. 30, 2014

(54) USB DRIVE ASSEMBLY

(71) Applicant: ZH-TEK Technologies Co., Ltd., New Taipei City (TW)

(72) Inventor: Yi Chia CHAN, New Taipei City (TW)

(21) Appl. No.: 13/921,360

(22) Filed: Jun. 19, 2013

(30) Foreign Application Priority Data
Apr. 25, 2013 (TW) 102207596

(51) Int. Cl. H05K 5/00

(52) U.S. Cl. CPC H05K 5/0039; H05K 5/0069
USPC 361/752

(57) ABSTRACT

A USB drive assembly, which is specifically referred to a joint assembly of USB drive and is configured by a casing, an isolated base, and a circuit board, wherein the conducting pins laid through the isolated base and the circuit board are tightly and electrically joined together, and all parts are assembled efficiently free from time consuming soldering process.

### BACKGROUND OF THE INVENTION

1. Field of the Invention

The present invention relates to a USB drive assembly, comprising a combination structure of a casing which is longitudinally formed with a hollow space and configured with two front stoppers toward the insertion direction, an isolated base which configured with a plural of pins and a fixing notch at the back, and a circuit board which is stopped by the said fixing notch. Both joint structure of the isolated base and the circuit board are firmly wrapped and inserted into the casing. Therefore, the present invention can be assembled efficiently without traditional soldering process and be applied in various USB connectors or similar connecting structure.

2. Description of Prior Art

The USB (Universal Serial Bus) connectors had been widely adopted as a standard port to function as a transmission interface between the computer and external peripherals. Especially, USB connectors are popularly used in memory storage device and equipped with function of ‘hot plugging’ or ‘plug and play’. Following the trend to be lighter, thinner and smaller, there are several USB connectors' specification had been released. They are standard A type, B type, Mini USB and Micro USB. So far, most of the USB connectors adopted in portable drive are standard A type. However, Micro USB was used in mobile phone and mini laptop for the recent years. There must be some bridge to connect between A type and Micro USB for expanding the memory size.

Prior USB connectors usually adopted a metal casing to wrap a plastic isolated base which is laid with a plural of conducting pins. And, one side of those pins are soldered with corresponding conducting pads on the circuit board to transmit signals. Thus, during the process of manufacturing, soldering had become an inconvenient and time-consuming routine job, and that led to a low efficiency for mass production of USB.

In view of the above discussed problems, the present invention aims to provide a convenient assembly without traditional soldering procedure, and provides a firmly joint structure, a convenient and efficient method to shorten prior USB connector manufacturing process. Above all, the present invention can effectively enhance the efficiency and speed of USB connectors production. Therefore, the prior USB connectors need to be improved.

### SUMMARY OF THE INVENTION

The primary object of the present invention is to provide a combination structure of a USB drive assembly which provides a simple and quicker manufacturing efficiency. To achieve the aimed purpose, the present invention comprising:

a casing, which is longitudinally formed with a hollow space and configured with two front stoppers located at both side corners toward the insertion direction;

an isolated base, which is assembled at the inner front of the said casing and is configured with a fixing block at the back and a plural of conducting pins, wherein the conducting pins are extended as bending ends through the fixing block and a fixing notch is formed at the lower position of the fixing block; and

a circuit board, which is assembled at the inner rear position of the hollow casing, and is laid with corresponding conducting pads on top surface to electrically connect with said bending ends of pins, and is stopped by the said fixing notch of the isolated base.

During the assembly process, the isolated base is forward inserted into the hollow casing and then the circuit board is put forward against the fixing notch to enable the bending ends to securely touch those conducting pads on the circuit board. By such an assembly, the present invention provides enables a simple and quicker manufacturing efficiency without traditional soldering process.

Meanwhile, the front end of the hollow casing is formed as a narrower insertion part and then is widely configured with two front stoppers toward the insertion direction right behind the insertion part. The front end of isolated base is assembled into the insertion part and the rear fixing block is located thereafter and is firmly hindered the front stoppers. Therefore, the isolated base is tightly fit into the inner surface of the casing. To be noted, before the joint assembly, the lower tip of the bending ends has a position lower than the conducting pads laid on the surface of the circuit board. Also, the circuit board is firmly wrapped by the casing. Besides, the casing is extended and formed as at least a rear stopper (not shown) to securely hold the circuit board and keep it tightly connect with the fixing block.

Furthermore, the casing is configured with two upper protruding parts on top surface, and, at the rear position, is formed with a back part. The back part is configured with a rear plate, and a fixing plate, which is jointly assembled over the circuit board. And, the fixing plate is configured with two lower recessing parts to correspondingly and is firmly stuck with said two upper protruding parts on top surface of casing. The front edge of the fixing plate is formed as slant surfaces both sides toward the circuit board.

By the joint structure described above, the present invention, comprising a combination structure of a casing, which is longitudinally formed with a hollow space and configured with two front stoppers toward the insertion direction, an isolated base which configured with a plural of pins and a fixing notch at the back, and a circuit board which is stopped by the said fixing notch. Both joint structure of the isolated base and the circuit board are firmly wrapped and inserted into the casing. Therefore, the present invention can be assembled efficiently without traditional soldering process and be applied in various USB connectors or similar connecting structures.

The function and structure of practical embodiments can be further understood via the drawings listed below.

### BRIEF DESCRIPTION OF THE DRAWINGS AND ELEMENTS

The present invention can be fully understood from the following detailed description and preferred embodiment with reference to the accompanying drawings, in which:

FIG. 1 illustrates a three-dimensional element decomposition view of the present invention.

FIG. 2 illustrates a three-dimensional composition view of the present invention.

FIG. 3 illustrates a schematic cross-section view of the present invention.

FIG. 4 illustrates a partial elevation view related to the present invention.

The elements related to the present invention are listed as follows:

| | |
|---|---|
| 1, casing | 2, isolated base |
| 3, circuit board | 4, back part |
| 5, pins | 11, insersion part |
| 12, front stopper | 13, upper protruding part |
| 21, fixing block | 22, fixing notch |
| 31, conducting pads | 41, rear plate |
| 42, fixing plate | 43, lower recessing part |
| 51, bending end | |

### DETAILED DESCRIPTION OF THE PREFERRED EMBODIMENTS

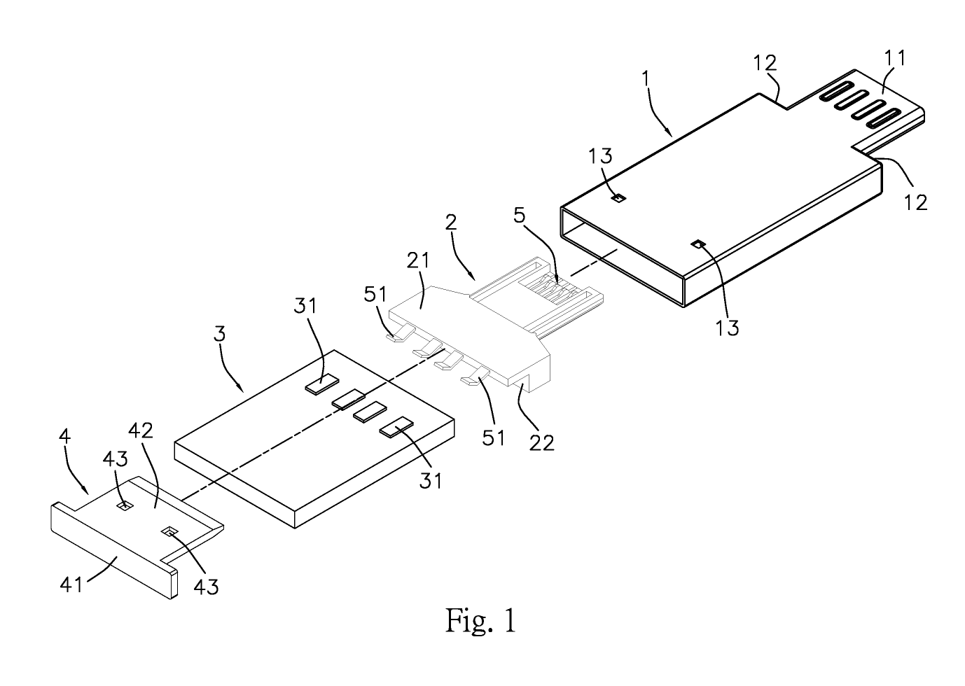

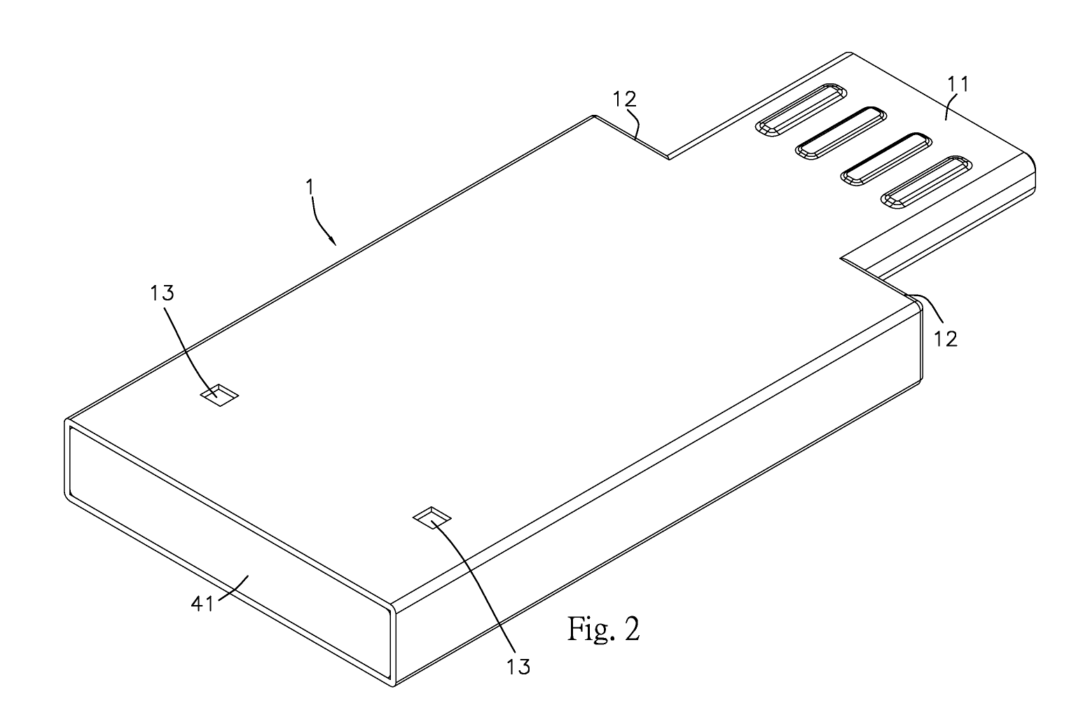

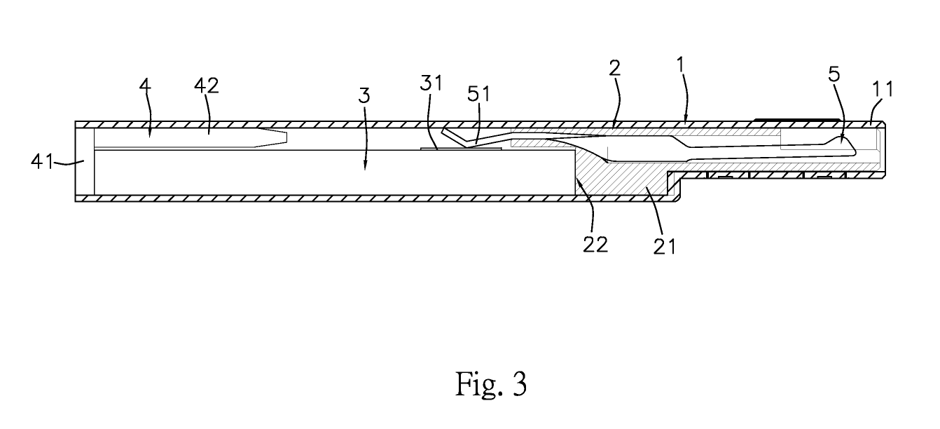

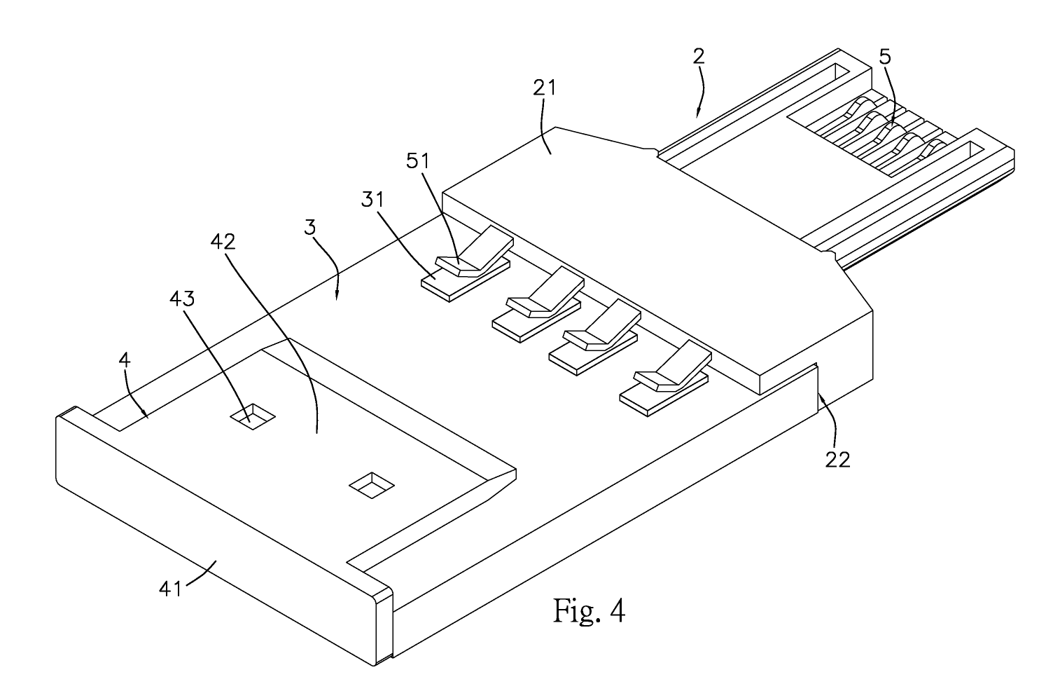

Please refer to FIG. 1 to FIG. 4. They respectively illustrate a three-dimensional element decomposition view, a composition view, a schematic cross-section view and a partial elevation view related to the present invention.

The present invention, a USB drive assembly, comprises: a casing 1, an isolated base 2 and a circuit board 3. The casing 1 is formed as a narrower insertion part 11 and then is widely configured with two front stoppers 12 located at both side corners toward the insertion direction right behind the insertion part 11, and is longitudinally formed with a hollow space. The casing is configured with two upper protruding parts 13 on top surface.

The isolated base 2, configured with a fixing block 21 at the back and a plural of conducting pins 5, has its front end slide into the insertion part 11 and is assembled at the inner front of the said casing 1. The conducting pins are extended as bending ends through the fixing block 21, located at the rear position of isolated base 2, and a fixing notch 22 is formed at the lower position of the fixing block 21. The isolated base 2 is then tightly fit into the inner surface of the casing 1. The conducting pins 5, extended through the fixing block 21, formed as bending ends 51 with a V type of right angle (90 degrees) or others to electrically contact the circuit board 3.

The circuit board 3 is assembled at the inner rear position of the hollow casing 1, and is laid with corresponding conducting pads 31 on top surface to electrically connect with said bending ends 51 of pins 5, and is stopped by the said fixing notch 22 of the isolated base 2. To be noted, before the joint assembly, the lower tip of the bending ends 51 has a position lower than that of the conducting pads 31 laid on the surface of the circuit board 3. After that, the lower tip of the bending ends 51 is securely connected with the conducting pads 31. Thus, the circuit board 3 is firmly wrapped by the casing 1. Besides, according to another embodiment, the casing 1 is extended and formed as at least a rear stopper (not shown) to securely hold the circuit board 3 and keep it tightly connect with the fixing block.

The casing 1 is further configured with a back part 4 which is formed with a rear plate 41 at the rear position, and a fixing plate 42 jointly assembled over the circuit board 3. The fixing plate 42 is fit between the inner surface of the casing 1 and the top surface of the circuit board 3. And, the fixing plate 42 is configured with two lower recessing parts 43 to correspondingly and firmly stick with said two upper protruding parts 13 on top rear surface of casing 1. The front edge of the fixing plate 42 is formed as slant surfaces both sides toward the circuit board 3. By this joint assembly, the circuit board 3 is limited between the rear plate 41 and the fixing notch 22, and is pressed by the fixing plate 42. The complete joint structure is secured by those corresponding upper protruding parts 13 and lower recessing parts 43.

By the joint structure described above, the present invention, comprising a combination structure of a casing 1, which is longitudinally formed with a hollow space and configured with two front stoppers 12 toward the insertion direction, an isolated base 2 which configured with a plural of pins 5 and a fixing notch 22 at the back, and a circuit board 3 which is stopped by the said fixing notch22. Both surrounding surface of the joint structure (the isolated base 2 and the circuit board 3) are firmly wrapped and inserted into the casing 1. Therefore, the present invention can be assembled efficiently without traditional soldering process and be applied in various USB connectors or similar connecting structures.

Of course, it is to be understood that the embodiments described herein are merely some illustrations related to the objects of the invention and that a wide variety of modifications thereto may be adopted without departing from the purpose and the scope of the present invention as set forth in the following claims.

What is claimed is:

1. A USB drive assembly, comprising:
a casing, which is longitudinally formed with a hollow space;
an isolated base, which is assembled at the inner front of the said casing and is configured with a fixing block at the back and a plural of conducting pins, wherein the conducting pins are extended as bending ends through the fixing block and a fixing notch is formed at the lower position of the fixing block; and
a circuit board, which is assembled at the inner rear position of the hollow casing, and is laid with corresponding conducting pads on top surface to electrically connect with said bending ends of pins, and is stopped by the said fixing notch of the isolated base.

2. A USB drive assembly according to claim 1, wherein the front end of the hollow casing is formed as a narrower insertion part and then is widely configured with two front stoppers, located at both side corners, toward the insertion direction right behind the insertion part.

3. A USB drive assembly according to claim 1, wherein the surrounding surface of the isolated base is wrapped by the inner surface of the casing.

4. A USB drive assembly according to claim 1, wherein the lower tip of the bending ends has a position lower than that of the conducting pads laid on the surface of the circuit board before the joint assembly.

5. A USB drive assembly according to claim 1, wherein the surrounding surface of the circuit board is wrapped by the inner surface of the casing.

6. A USB drive assembly according to claim 1, wherein the casing is extended and formed as at least a rear stopper to hold the circuit board and keep it connect with the fixing block.

7. A USB drive assembly according to claim 1, wherein the casing, at the rear position, is formed as a back part which is configured with a rear plate, and a fixing plate to be jointly assembled over the circuit board.

8. A USB drive assembly according to claim 7, wherein the circuit board fixing plate is fit between the inner surface of the casing and the top surface of the circuit board.

9. A USB drive assembly according to claim 7, wherein the fixing plate is configured with two lower recessing parts to correspondingly stick with two upper protruding parts configured on top rear surface of casing.

10. A USB drive assembly according to claim 7, wherein the front edge of the fixing plate is formed as slant surfaces both sides toward the circuit board.

11. A USB drive assembly according to claim 7, wherein the circuit board is limited between the rear plate and the fixing notch, and is pressed by the fixing plate.
